(19) United States
(12) Patent Application Publication
(10) Pub. No.: US 2016/0013051 A1
(43) Pub. Date: Jan. 14, 2016

(54) SEMICONDUCTOR DEVICE AND RELATED MANUFACTURING METHOD

(71) Applicant: Semiconductor Manufacturing International (Shanghai) Corporation, Shanghai (CN)

(72) Inventors: Yizhi ZENG, Shanghai (CN); Jie ZHAO, Shanghai (CN)

(21) Appl. No.: 14/748,491

(22) Filed: Jun. 24, 2015

(30) Foreign Application Priority Data
Jul. 9, 2014 (CN) 201410325676.8

(51) Int. Cl. H01L 21/02; H01L 21/8234; H01L 21/3105; H01L 27/088; H01L 29/66

(52) U.S. Cl. CPC H01L 21/02345; H01L 27/088; H01L 29/66545; H01L 21/0206; H01L 21/3105; H01L 21/823437

(57) ABSTRACT

A method for manufacturing a semiconductor device may include the following steps: providing a substrate structure; forming, on the substrate structure, a first gate structure, a second gate structure, and a trench between the first gate structure and the second gate structure; providing a liner that covers the first gate structure, the second gate structure, and a bottom of the trench; after the liner has been provided, providing a dielectric layer that fills the trench; and performing one or more iterations of a treatment process on the dielectric layer, wherein the treatment process includes performing a curing process on the dielectric layer and subsequently performing an annealing process on the dielectric layer.

### CROSS-REFERENCE TO RELATED APPLICATION

This application claims priority to and benefit of Chinese Patent Application No. 201410325676.8, filed on 9 Jul. 2014; the Chinese Patent Application is incorporated herein by reference in its entirety.

### BACKGROUND OF THE INVENTION

The present invention is related to a semiconductor device and a method for manufacturing the semiconductor device.

In a process for manufacturing a semiconductor device, a dielectric layer may be formed for insulating conductive elements. A flowable chemical vapor deposition (FCVD) process may be performed for forming the dielectric layer.

For preventing the FCVD process from damaging elements of the semiconductor device, the FCVD process may be performed at a temperature under 600 degrees Celsius. The process temperature may lead to insufficient density of the dielectric layer, such that undesirable voids may exist in the dielectric layer and/or undesirable gaps may exist between the dielectric layer and other elements in the semiconductor device. As a result, the quality of the semiconductor device may be unsatisfactory.

### SUMMARY

An embodiment of the present invention may be related to a method for manufacturing a semiconductor device. The method may include the following steps: providing a substrate structure; providing, on the substrate structure, a first gate structure, a second gate structure, and a trench between the first gate structure and the second gate structure; providing a liner that may cover the first gate structure, the second gate structure, and a bottom of the trench; after the liner has been provided, providing a dielectric layer that fills the trench; and performing one or more iterations of a treatment process on the dielectric layer. The treatment process may include the following steps: performing a curing process on the dielectric layer; and subsequently performing an annealing process on the dielectric layer.

The liner may be formed of an oxide material. The liner may be formed through at least one of an atomic layer deposition process and a chemical vapor deposition process. A minimum thickness of the liner may be in a range of 5 nm to 15 nm.

The step of providing the dielectric layer may include the following steps: performing one or more iterations of an intermediate process; and subsequently providing an overlying dielectric material layer that may overlie one or more intermediate dielectric material layers resulted from the one or more iterations of the intermediate process. The intermediate process may include the following steps: providing an intermediate dielectric material layer in the trench; and subsequently performing an intermediate curing process on the intermediate dielectric material layer. The dielectric layer may include the one or more intermediate dielectric material layers and the overlying dielectric material layer.

The overlying dielectric material layer may cover the first gate structure and the second gate structure. The overlying dielectric material layer extends into the trench.

The intermediate process may further include the following step: after the intermediate curing process, performing a cleaning process on the intermediate dielectric material layer to generate a set of reactive species at the intermediate dielectric material layer.

Two or more iterations of the intermediate process may be performed before the overlying dielectric material layer is provided.

The method may include the following step: before the step of providing the dielectric layer, performing a cleaning process on the liner to generate a set of reactive species at the liner. At least one of ammonia, hydrogen peroxide, deionized water, and ozone may be used in the cleaning process.

In the treatment process, at least one of deionized water and ozone may be used in the curing process. The annealing process may include at least one of a steam annealing process and a dry annealing process. The annealing process may be performed at a temperature in a range of 400 degrees Celsius to 500 degrees Celsius. In the method, the total number of the iterations of the treatment process may be equal to 3 or 4.

The method may include the following step: before the liner may be provided, providing an etch stop layer on the first gate structure, the second gate structure, and the bottom of the trench. The liner may be subsequently formed on the etch stop layer.

The first gate structure may include the following elements: a dummy gate member formed of silicon; and a gate dielectric layer positioned between the dummy gate member and the substrate structure.

An embodiment of the present invention may be related to a semiconductor device manufactured using one or more of the aforementioned steps. The semiconductor device may include the following elements: a substrate structure; a first gate structure positioned on the substrate structure; a second gate structure positioned on the substrate structure; a trench positioned between the first gate structure and the second gate structure; a liner that covers the first gate structure, the second gate structure, and a bottom of the trench; and a dielectric layer that covers the liner and fills the trench.

The liner may be formed of an oxide material. A minimum thickness of the liner may be in a range of 5 nm to 15 nm.

The semiconductor device may further include an etch stop layer that is positioned between the liner and each of the first gate structure, the second gate structure, and the substrate structure.

The first gate structure may include the following elements: a dummy gate member formed of silicon; and a gate dielectric layer positioned between the dummy gate member and the substrate structure.

An embodiment of the present invention may be related to an electronic device that includes an electronic component and includes a semiconductor device. The semiconductor device may be manufactured using one or more of the aforementioned steps and may be electrically connected to the electronic component.

According to embodiments of the invention, in a process for manufacturing semiconductor devices, liner formation, liner cleaning, dielectric layer curing, dielectric layer cleaning, dielectric layer annealing, and/or process iterations may enable optimization of density and filling capability of dielectric layers. Sufficiently low process temperatures may prevent processes from causing damage to elements of the semiconductor devices. Therefore, defects (e.g., voids or gaps) in the semiconductor devices may be substantially minimized or prevented. Advantageously, satisfactory quality of the semiconductor devices and a satisfactory yield of the manufacturing process may be substantially attained.

The above summary is related to some of many embodiments of the invention disclosed herein and is not intended to limit the scope of the invention.

### BRIEF DESCRIPTION OF THE DRAWINGS

FIG. 1, FIG. 2, FIG. 3, FIG. 4, and FIG. 5 show schematic diagrams (e.g., schematic cross-sectional views) that illustrate elements and/or structures formed in a method for manufacturing a semiconductor device in accordance with one or more embodiments of the present invention.

FIG. 6 shows a flowchart that illustrates steps in a method for manufacturing a semiconductor device in accordance with one or more embodiments of the present invention.

FIG. 7, FIG. 8, FIG. 9, FIG. 10, FIG. 11, FIG. 12, and FIG. 13 show schematic diagrams (e.g., schematic cross-sectional views) that illustrate elements and/or structures formed in a method for manufacturing a semiconductor device in accordance with one or more embodiments of the present invention.

FIG. 14 shows a flowchart that illustrates steps in a method for manufacturing a semiconductor device in accordance with one or more embodiments of the present invention.

### DETAILED DESCRIPTION

Example embodiments of the present invention are described with reference to the accompanying drawings. As those skilled in the art would realize, the described embodiments may be modified in various different ways, all without departing from the spirit or scope of the present invention. Embodiments of the present invention may be practiced without some or all of these specific details. Well known process steps and/or structures may not have been described in detail in order to not unnecessarily obscure the present invention.

The drawings and description are illustrative and not restrictive. Like reference numerals may designate like (e.g., analogous or identical) elements in the specification. Repetition of description may be avoided.

The relative sizes and thicknesses of elements shown in the drawings are for facilitate description and understanding, without limiting the present invention. In the drawings, the thicknesses of some layers, films, panels, regions, etc., may be exaggerated for clarity.

Illustrations of example embodiments in the figures may represent idealized illustrations. Variations from the shapes illustrated in the illustrations, as a result of, for example, manufacturing techniques and/or tolerances, may be possible. Thus, the example embodiments should not be construed as limited to the shapes or regions illustrated herein but are to include deviations in the shapes. For example, an etched region illustrated as a rectangle may have rounded or curved features. The shapes and regions illustrated in the figures are illustrative and should not limit the scope of the example embodiments.

Although the terms “first”, “second”, etc. may be used herein to describe various elements, these elements, should not be limited by these terms. These terms may be used to distinguish one element from another element. Thus, a first element discussed below may be termed a second element without departing from the teachings of the present invention. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

If a first element (such as a layer, film, region, or substrate) is referred to as being “on”, “neighboring”, “connected to”, or “coupled with” a second element, then the first element can be directly on, directly neighboring, directly connected to, or directly coupled with the second element, or an intervening element may also be present between the first element and the second element. If a first element is referred to as being “directly on”, “directly neighboring”, “directly connected to”, or “directed coupled with” a second element, then no intended intervening element (except environmental elements such as air) may also be present between the first element and the second element.

Spatially relative terms, such as “beneath”, “below”, “lower”, “above”, “upper”, and the like, may be used herein for ease of description to describe one element or feature's spatial relationship to another element(s) or feature(s) as illustrated in the figures. It will be understood that the spatially relative terms may encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein should be interpreted accordingly.

The terminology used herein is for the purpose of describing particular embodiments and is not intended to limit the invention. As used herein, the singular forms, “a”, “an”, and “the” may indicate plural forms as well, unless the context clearly indicates otherwise. The terms “includes” and/or “including”, when used in this specification, may specify the presence of stated features, integers, steps, operations, elements, and/or components, but may not preclude the presence or addition of one or more other features, integers, steps, operations, elements, components, and/or groups.

Unless otherwise defined, terms (including technical and scientific terms) used herein have the same meanings as commonly understood by one of ordinary skill in the art related to this invention. Terms, such as those defined in commonly used dictionaries, should be interpreted as having meanings that are consistent with their meanings in the context of the relevant art and should not be interpreted in an idealized or overly formal sense unless expressly so defined herein.

The term “connect” may mean “electrically connect”. The term “insulate” may mean “electrically insulate”. The term “conductive” may mean “electrically conductive”

Unless explicitly described to the contrary, the word “comprise” and variations such as “comprises”, “comprising”, “include”, or “including” may imply the inclusion of stated elements but not the exclusion of other elements.

Various embodiments, including methods and techniques, are described in this disclosure. Embodiments of the invention may also cover an article of manufacture that includes a non-transitory computer readable medium on which computer-readable instructions for carrying out embodiments of the inventive technique are stored. The computer readable medium may include, for example, semiconductor, magnetic, opto-magnetic, optical, or other forms of computer readable medium for storing computer readable code. Further, the invention may also cover apparatuses for practicing embodiments of the invention. Such apparatus may include circuits, dedicated and/or programmable, to carry out operations pertaining to embodiments of the invention. Examples of such apparatus include a general purpose computer and/or a dedicated computing device when appropriately programmed and may include a combination of a computer/computing device and dedicated/programmable hardware circuits (such as electrical, mechanical, and/or optical circuits) adapted for the various operations pertaining to embodiments of the invention.

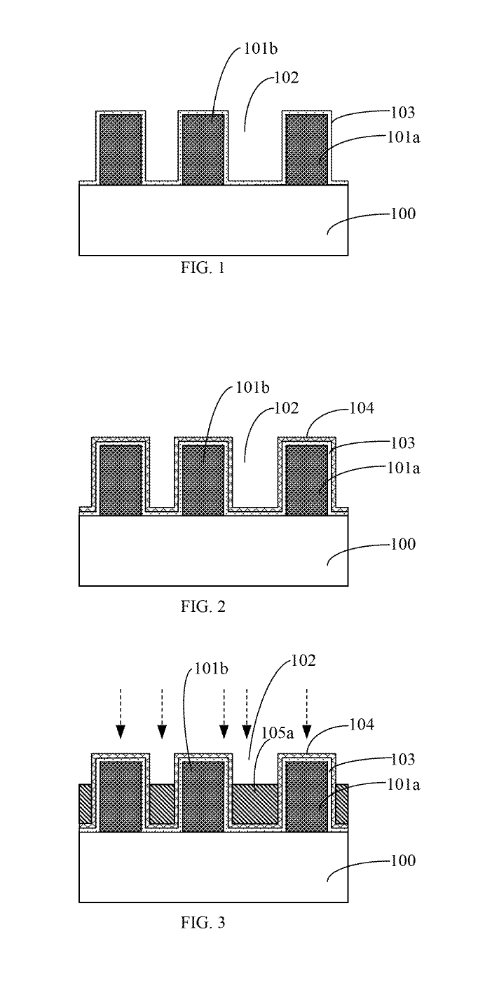

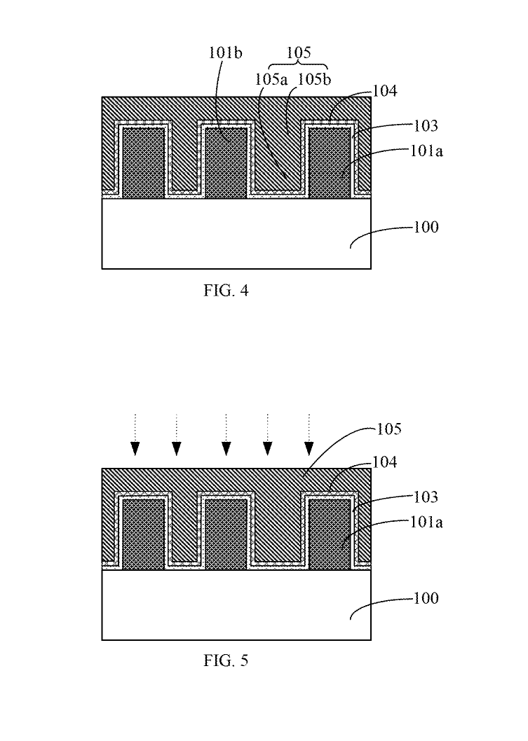

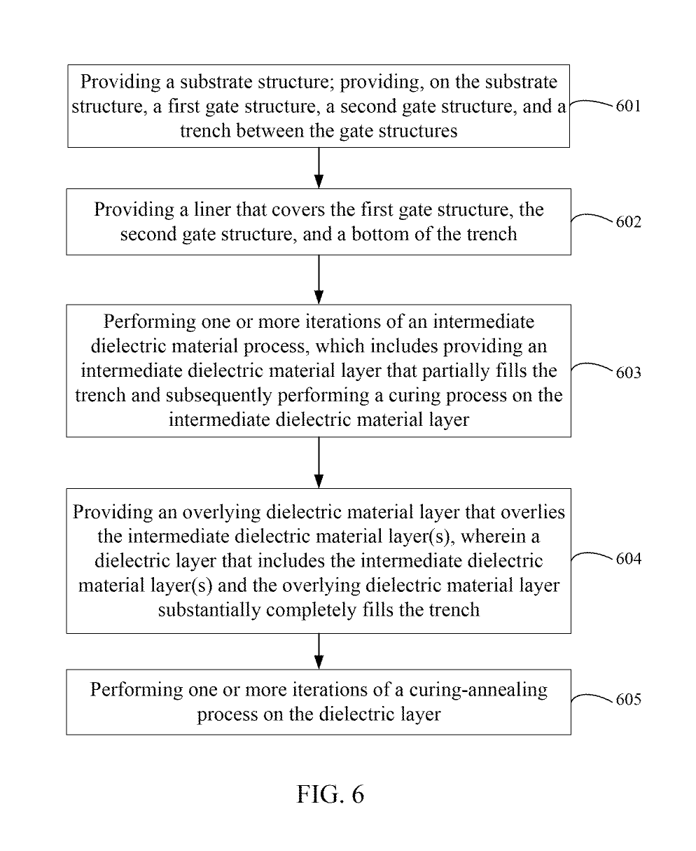

FIG. 1, FIG. 2, FIG. 3, FIG. 4, and FIG. 5 show schematic diagrams (e.g., schematic cross-sectional views) that illustrate elements and/or structures formed in a method for manufacturing a semiconductor device in accordance with one or more embodiments of the present invention. FIG. 6 shows a flowchart that illustrates steps in a method for manufacturing a semiconductor device in accordance with one or more embodiments of the present invention.

Referring to FIG. 6, the method may include steps 601, 602, 603, 604, and 605.

Referring to FIG. 6 and FIG. 1, the step 601 may include providing a substrate structure 100 and may include providing, on the substrate structure 100, a plurality of gate structures (e.g., a first gate structure 101a and a second gate structure 101b) and a plurality of trenches (e.g., a trench 102) between the gate structures.

The substrate structure 100 may include a semiconductor substrate. The semiconductor substrate may include at least one of a silicon (Si) substrate member, a silicon-on-insulator (SOI) substrate member, a strained-silicon-on-insulator (SSOI) substrate member, a stacked-silicon-germanium-on-insulator (S—SiGeOI) member, a silicon-germanium-on-insulator (SiGeOI) substrate member, a germanium-on-insulator (GeOI) substrate member, etc. The semiconductor substrate may include at least one shallow trench isolation (STI) structure configured to isolate active regions. The STI structure may be formed of one or more low-k dielectric materials, such as one or more of silicon oxide, silicon nitride, silicon oxynitride, fluorine-doped glass, etc. The semiconductor substrate may include one or more doped wells. The semiconductor substrate may include one or more fin structures.

Each of the gate structures may include a dummy gate member and a gate dielectric layer, which may be positioned between the dummy gate member and the substrate structure 100. The gate dielectric layer may be formed of one or more high-k dielectric materials, such as one or more of hafnium oxide, hafnium silicon oxide, hafnium silicon oxynitride, lanthanum oxide, zirconium oxide, zirconium silicon oxide, titanium oxide, tantalum oxide, barium strontium titanium oxide, barium titanium oxide, strontium titanium oxide, etc. The gate dielectric layer may be formed through one or more of a chemical vapor deposition (CVD) process, a physical vapor deposition (PVD) process, etc. The dummy gate member may be formed of polycrystalline silicon (or polysilicon) and may be formed through a low-pressure chemical vapor deposition (LPCVD) process. The trench 102 may be formed between the first gate structure 101a and the second gate structure 101b as a result of an etching process performed to form the first gate structure 101a and the second gate structure 101b.

The step 601 may further include providing an etch stop layer 103 (e.g., a contact hole etch stop layer) on the first gate structure 101a, the second gate structure 101b, and the bottom of the trench 102. The etch stop layer 103 may be formed of silicon nitride and/or one or more of other suitable materials. The etch stop layer 103 may be formed through one or more of a chemical vapor deposition (CVD) process, a physical vapor deposition (PVD) process, a nitriding process, etc.

Referring to FIG. 6, FIG. 1, and FIG. 2, subsequent to the step 601, the step 602 may include providing a liner 104 on the etch stop layer 103. The liner 104 may cover the first gate structure 101a, the second gate structure 101b, and a bottom of the trench 102. The liner 104 may be formed of one or more of an oxide material, a nitride material, etc., such as an oxide. The liner 104 may be formed through one or more of a chemical vapor deposition (CVD) process, an atomic layer deposition (ALD) process, etc. A minimum thickness of the liner 104 (in a direction perpendicular to a bottom surface of the substrate structure 100) may be in a range of 5 nm to 15 nm, e.g., about 7 nm or about 10 nm. The liner 104 may include a first liner portion, a second liner portion, and a third liner portion, each being positioned between the first gate structure 101a and the second gate structure 101b. The first liner portion may be spaced from the second liner portion and may be connected to the second liner portion through the third liner portion. The third liner portion may be positioned at the bottom of the trench 102.

Referring to FIG. 6, FIG. 2, and FIG. 3, subsequent to the step 602, the step 603 may include performing one or more iterations of an intermediate dielectric material process. The intermediate dielectric material process may include providing an intermediate dielectric material layer (such as the dielectric material layer 105a illustrated in FIG. 3) in the trench 102 and subsequently performing an intermediate curing process (represented by dotted arrows in FIG. 3) on the intermediate dielectric material layer.

The intermediate dielectric material layer (e.g., the layer 105a) may be a flowable dielectric material layer and may partially (not completely) fill the trench 102. The intermediate dielectric material layer may be formed of one or more of flowable silicon dioxide (SiO₂), flowable silicon oxynitride (SiOₓN_{y}), etc. The intermediate dielectric material layer may be formed through spin-on deposition (SOD) of one or more dielectric materials, such as SOD of one or more of silicates, siloxanes, methyl silsesquioxane (MSQ), hydrogen silsesquioxane (HSQ), MSQ-HSQ, perhydrosilazane (TCPS), and perhydro-polysilazane (PSZ).

In an embodiment, the intermediate dielectric material layer may be formed of flowable silicon dioxide (SiO₂) and may be formed through a flowable chemical vapor deposition (FCVD) process. In the FCVD process, a silicon-containing precursor (e.g., an organic silane) may react with an oxygen-containing precursor (e.g. one or more of oxygen, ozone, and nitrogen oxides) to form the silicon oxide intermediate dielectric material layer on the substrate structure 100 and on the elements already positioned on the substrate structure 100. The silicon oxide intermediate dielectric material layer may have a substantially high concentration of silicon-hydroxide (Si—OH) bonds. The bonds may promote and/or optimize the flowability (or mobility) of silicon oxide material of the intermediate dielectric material layer, such that the silicon oxide material may rapidly move into gaps and/or trenches on the substrate structure 100 and/or on the elements already positioned on the substrate structure 100.

The intermediate curing process may involve exposing the intermediate dielectric material layer (e.g., the layer 105a) to at least one of deionized water and ozone (O₃). In the intermediate curing process, the flow rate of ozone may be in a range of 100 sccm to 5000 sccm, the process temperature may be in a range of 10 degrees Celsius to 500 degrees Celsius, and the process pressure may be in a range of 1 torr to 760 torr. The intermediate curing process may transform Si—O bond networks in the intermediate dielectric material layer. As a result, the density of the intermediate dielectric material layer may be maximized. Advantageously, defects (e.g., voids) in the structure illustrated in FIG. 3 may be substantially minimized or prevented.

In an embodiment, the intermediate dielectric material process may be performed only once in the step 603.

In an embodiment, two or more iterations of the intermediate dielectric material process may be performed in the step 603.

Referring to FIG. 6, FIG. 3, and FIG. 4, subsequent to the step 603, the step 604 may include providing an overlying dielectric material layer 105b that overlies the one or more intermediate dielectric material layers (e.g., the layer 105a) that have been formed in the step 603. The overlying dielectric material layer may extend into the trench 102. The overlying dielectric material layer 105b may extend beyond the trench 102. The overlying dielectric material layer 105b may cover the first gate structure 101a and the second gate structure 101b. A material of the intermediate dielectric material layer 105a may be the same as a material of the overlying dielectric material layer 105b.

The overlying dielectric material layer 105b may be formed of one or more of flowable silicon dioxide (SiO₂), flowable silicon oxynitride (SiOₓN_{y}), etc. The overlying dielectric material layer 105b may be formed through spin-on deposition (SOD) of one or more dielectric materials, such as SOD of one or more of silicates, siloxanes, methyl silsesquioxane (MSQ), hydrogen silsesquioxane (HSQ), MSQ-HSQ, perhydrosilazane (TCPS), and perhydro-polysilazane (PSZ).

In an embodiment, the overlying dielectric material layer 105b may be formed of flowable silicon dioxide (SiO₂) and may be formed through a flowable chemical vapor deposition (FCVD) process. In the FCVD process, a silicon-containing precursor (e.g., an organic silane) may react with an oxygen-containing precursor (e.g. one or more of oxygen, ozone, and nitrogen oxides) to form the silicon oxide overlying dielectric material layer 105b on the substrate structure 100 and on the elements already positioned on the substrate structure 100. The silicon oxide overlying dielectric material layer 105b may have a substantially high concentration of silicon-hydroxide (Si—OH) bonds. The bonds may promote and/or optimize the flowability (or mobility) of silicon oxide material of the intermediate dielectric material layer, such that the silicon oxide material may rapidly move into gaps and/or trenches on the elements already positioned on the substrate structure 100 and may rapidly cover the gate structures 101a and 101b.

As a result, a dielectric layer 105 that includes the one or more intermediate dielectric material layers (e.g., the layer 105a) and the overlying dielectric material layer 105b may be formed. The dielectric layer 105 may substantially completely fill the trench 102 and may cover both the gate structures 101a and 101b.

Referring to FIG. 6, FIG. 4, and FIG. 5, subsequently to the step 604, the step 605 may include performing one or more iterations of a dielectric layer treatment process on the dielectric layer 105. The treatment process may include performing a curing process on the dielectric layer 105 and subsequently performing an annealing process on the dielectric layer 105.

The curing process may involve exposing the dielectric layer 105a to at least one of deionized water and ozone (O₃). In the curing process, the flow rate of ozone may be in a range of 100 sccm to 5000 sccm, the process temperature may be in a range of 10 degrees Celsius to 500 degrees Celsius, and the process pressure may be in a range of 1 torr to 760 torr. The curing process may transform Si—O bond networks in the dielectric layer 105. As a result, the density of the dielectric layer 105 may be maximized. Advantageously, defects (e.g., voids) in the structure illustrated in FIG. 5 may be substantially minimized or prevented.

The annealing process (represented by dotted arrows in FIG. 5) may include at least one of a steam annealing process, a dry annealing process, a plasma annealing process, an ultraviolet (UV) annealing process, an electron beam annealing process, a microwave annealing process, etc. One or more of dry nitrogen, dry helium, dray argon, etc. may be used in the dry annealing process.

In an embodiment, organic silane may be used as a source gas in the process of forming the dielectric layer 105, such that a substantial amount of carbon may be introduced to the oxide layer to form, for example, Si—C bonds and/or Si—O—C bonds. The annealing process may include a steam annealing process for replacing some Si—C bonds with Si—OH bonds in the dielectric layer 105. In the steam annealing process, the flow rate of water vapor may be in a range of 5 sccm to 20 sccm, and the process temperature may be in a range of 400 degrees Celsius to 500 degrees Celsius, e.g., 450 degrees Celsius. Subsequently, a dry annealing process may be performed on the dielectric layer 105 in a water-free atmosphere, e.g., in a dry nitrogen atmosphere, to convert the Si—OH bonds into silicon oxide bonds and to remove moisture from the dielectric layer 105.

The annealing process may be performed at a temperature in a range of 400 degrees Celsius to 500 degrees Celsius.

In an embodiment, for optimizing the quality of the dielectric layer 105, multiple iterations of the treatment process may be performed in the step 605. For example, the total number of the iterations of the treatment process may be equal to 3 or 4 in the step 605. Since the process temperatures for the curing process and the annealing process may be sufficiently low, the iterations of the treatment process may not cause significant damage to elements in the semiconductor device.

An embodiment of the present invention may be related to a high-k metal gate and/or gate-last process that may include one or more of the above-discussed steps. An embodiment of the present invention may be related to an interlayer dielectric layer formation process in a fin field-effect transistor (FinFET) manufacturing process, wherein the interlayer dielectric layer formation process may include one or more of the above-discussed steps.

According to embodiments of the invention, the liner structure and/or the curing, annealing, and process iterations may enable optimization of the density and filling capability of the dielectric layer 105. The sufficiently low process temperatures may prevent the processes from causing damage to elements of the semiconductor device. Therefore, defects (e.g., voids or gaps) in the semiconductor device may be substantially minimized or prevented. Advantageously, satisfactory quality of the semiconductor device and satisfactory manufacturing yield associated with the semiconductor device may be substantially attained.

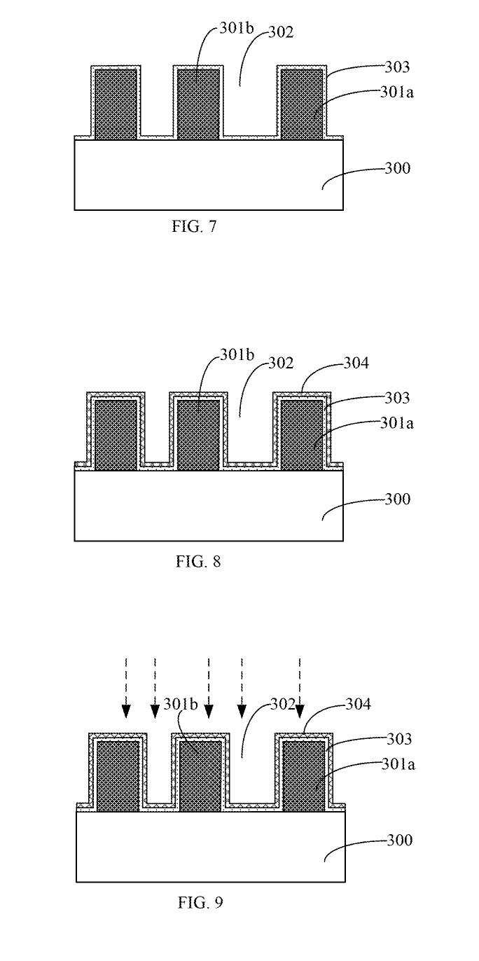

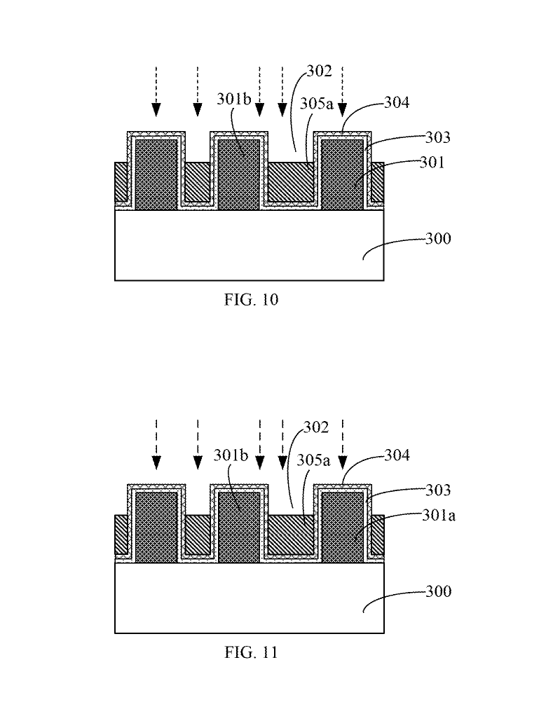

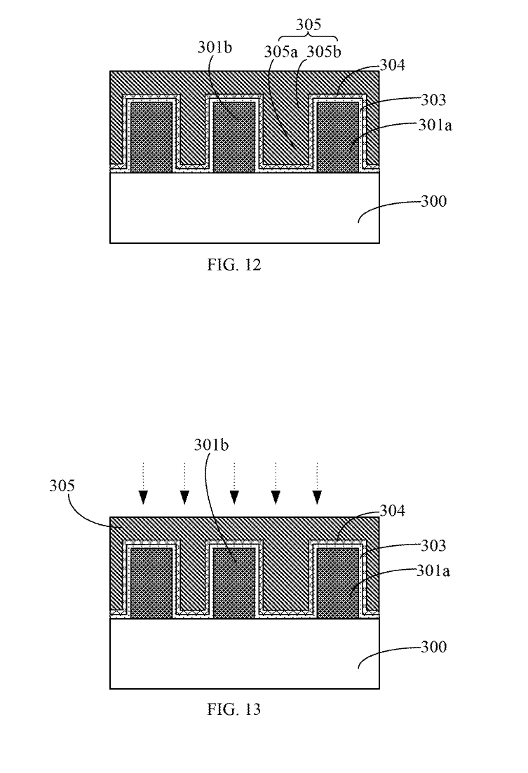

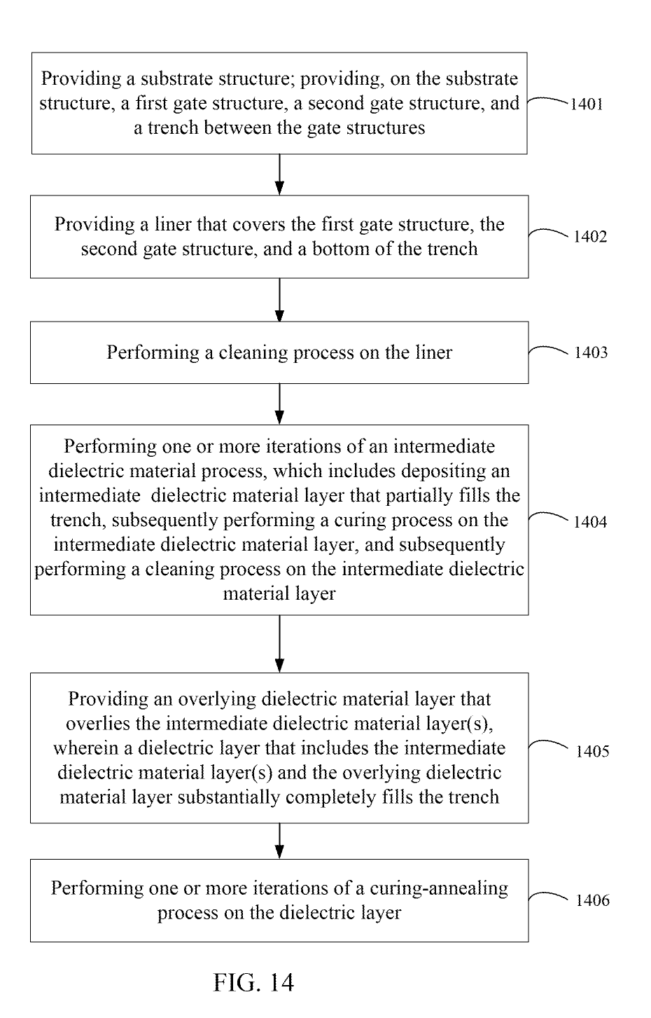

FIG. 7, FIG. 8, FIG. 9, FIG. 10, FIG. 11, FIG. 12, and FIG. 13 show schematic diagrams (e.g., schematic cross-sectional views) that illustrate elements and/or structures formed in a method for manufacturing a semiconductor device in accordance with one or more embodiments of the present invention. FIG. 14 shows a flowchart that illustrates steps in a method for manufacturing a semiconductor device in accordance with one or more embodiments of the present invention.

Referring to FIG. 14, the method may include steps 1401, 1402, 1403, 1404, 1405, and 1406.

Referring to FIG. 14 and FIG. 7, the step 1401 may include providing a substrate structure 300 and may include providing, on the substrate structure 300, a plurality of gate structures (e.g., a first gate structure 301a and a second gate structure 301b) and a plurality of trenches (e.g., a trench 302) between the gate structures.

The substrate structure 300 may include a semiconductor substrate. The semiconductor substrate may include at least one of a silicon (Si) substrate member, a silicon-on-insulator (SOI) substrate member, a strained-silicon-on-insulator (SSOI) substrate member, a stacked-silicon-germanium-on-insulator (S—SiGeOI) member, a silicon-germanium-on-insulator (SiGeOI) substrate member, a germanium-on-insulator (GeOI) substrate member, etc. The semiconductor substrate may include at least one shallow trench isolation (STI) structure configured to isolate active regions. The STI structure may be formed of one or more low-k dielectric materials, such as one or more of silicon oxide, silicon nitride, silicon oxynitride, fluorine-doped glass, etc. The semiconductor substrate may include one or more doped wells. The semiconductor substrate may include one or more fin structures.

Each of the gate structures may include a dummy gate member and a gate dielectric layer, which may be positioned between the dummy gate member and the substrate structure 300. The gate dielectric layer may be formed of one or more high-k dielectric materials, such as one or more of hafnium oxide, hafnium silicon oxide, hafnium silicon oxynitride, lanthanum oxide, zirconium oxide, zirconium silicon oxide, titanium oxide, tantalum oxide, barium strontium titanium oxide, barium titanium oxide, strontium titanium oxide, etc. The gate dielectric layer may be formed through one or more of a chemical vapor deposition (CVD) process, a physical vapor deposition (PVD) process, etc. The dummy gate member may be formed of polycrystalline silicon (or polysilicon) and may be formed through a low-pressure chemical vapor deposition (LPCVD) process. The trench 302 may be formed between the first gate structure 301a and the second gate structure 301b as a result of an etching process performed to form the first gate structure 301a and the second gate structure 301b.

The step 1401 may further include providing an etch stop layer 303 (e.g., a contact hole etch stop layer) on the first gate structure 301a, the second gate structure 301b, and the bottom of the trench 302. The etch stop layer 303 may be formed of silicon nitride and/or one or more of other suitable materials. The etch stop layer 303 may be formed through one or more of a chemical vapor deposition (CVD) process, a physical vapor deposition (PVD) process, a nitriding process, etc.

Referring to FIG. 14, FIG. 7, and FIG. 8, subsequent to the step 1401, the step 1402 may include providing a liner 304 on the etch stop layer 303. The liner 304 may cover the first gate structure 301a, the second gate structure 301b, and a bottom of the trench 302. The liner 304 may be formed of one or more of an oxide material, a nitride material, etc., such as an oxide. The liner 304 may be formed through one or more of a chemical vapor deposition (CVD) process, an atomic layer deposition (ALD) process, etc. A minimum thickness of the liner 304 (in a direction perpendicular to a bottom surface of the substrate structure 300) may be in a range of 5 nm to 15 nm, e.g., about 7 nm or about 30 nm. The liner 304 may include a first liner portion, a second liner portion, and a third liner portion, each being positioned between the first gate structure 301a and the second gate structure 301b. The first liner portion may be spaced from the second liner portion and may be connected to the second liner portion through the third liner portion. The third liner portion may be positioned at the bottom of the trench 302.

Referring to FIG. 14, FIG. 8, and FIG. 9, subsequent to the step 1402, the step 1403 may include performing a cleaning process (represented by dotted arrows in FIG. 9) on the liner 304 to generate a set of reactive species, e.g., a set of reactive oxygen species, at the liner 304. The reactive species may facilitate bonding between the liner and subsequently formed dielectric layers. At least one of ammonia, hydrogen peroxide, deionized water, and ozone may be used in the cleaning process. In an embodiment, a solution that includes ammonia, hydrogen peroxide, and deionized water may be used in the cleaning process.

Referring to FIG. 14, FIG. 9, FIG. 10, and FIG. 11, subsequent to the step 1403, the step 1404 may include performing one or more iterations of an intermediate dielectric material process. The intermediate dielectric material process may include providing an intermediate dielectric material layer (such as the dielectric material layer 305a illustrated in FIG. 10) in the trench 302, subsequently performing an intermediate curing process (represented by dotted arrows in FIG. 10) on the intermediate dielectric material layer, and subsequently performing an intermediate cleaning process (represented by dotted arrows in FIG. 11) on the intermediate dielectric material layer.

The intermediate dielectric material layer (e.g., the layer 305a) may be a flowable dielectric material layer and may partially (not completely) fill the trench 302. The intermediate dielectric material layer may be formed of one or more of flowable silicon dioxide (SiO₂), flowable silicon oxynitride (SiOₓN_{y}), etc. The intermediate dielectric material layer may be formed through spin-on deposition (SOD) of one or more dielectric materials, such as SOD of one or more of silicates, siloxanes, methyl silsesquioxane (MSQ), hydrogen silsesquioxane (HSQ), MSQ-HSQ, perhydrosilazane (perhydrosilazane, TCPS), and perhydro-polysilazane (PSZ).

In an embodiment, the intermediate dielectric material layer may be formed of flowable silicon dioxide (SiO₂) and may be formed through a flowable chemical vapor deposition (FCVD) process. In the FCVD process, a silicon-containing precursor (e.g., an organic silane) may react with an oxygen-containing precursor (e.g. one or more of oxygen, ozone, and nitrogen oxides) to form the silicon oxide intermediate dielectric material layer on the substrate structure 300 and on the elements already positioned on the substrate structure 300. The silicon oxide intermediate dielectric material layer may have a substantially high concentration of silicon-hydroxide (Si—OH) bonds. The bonds may promote and/or optimize the flowability (or mobility) of silicon oxide material of the intermediate dielectric material layer, such that the silicon oxide material may rapidly move into gaps and/or trenches on the substrate structure 300 and/or on the elements already positioned on the substrate structure 300.

The intermediate curing process (represented by dotted arrows in FIG. 10) may involve exposing the intermediate dielectric material layer (e.g., the layer 305a) to at least one of deionized water and ozone (O₃). In the intermediate curing process, the flow rate of ozone may be in a range of 300 sccm to 5000 sccm, the process temperature may be in a range of 30 degrees Celsius to 500 degrees Celsius, and the process pressure may be in a range of 1 torr to 7140 torr. The intermediate curing process may transform Si—O bond networks in the intermediate dielectric material layer. As a result, the density of the intermediate dielectric material layer may be maximized. Advantageously, defects (e.g., voids) in the structure illustrated in FIG. 10 may be substantially minimized or prevented.

The intermediate cleaning process (represented by dotted arrows in FIG. 11) may enable generation of a set of reactive species, e.g., a set of reactive oxygen species, at the intermediate dielectric material layer. The intermediate cleaning process may involve applying at least one of ammonia, hydrogen peroxide, deionized water, and ozone on the intermediate dielectric material layer to generate a set of reactive oxygen species at the intermediate dielectric material layer. In an embodiment, a solution that includes ammonia, hydrogen peroxide, and deionized water may be used in the intermediate cleaning process.

In an embodiment, the intermediate dielectric material process may be performed only once in the step 1404.

In an embodiment, two or more iterations of the intermediate dielectric material process may be performed in the step 1404. The multiple iterations of the intermediate dielectric material process may enable optimal filling of the trench 302 by intermediate dielectric material layers.

Referring to FIG. 14, FIG. 11, and FIG. 12, subsequent to the step 1404, the step 1405 may include providing an overlying dielectric material layer 305b that overlies the one or more intermediate dielectric material layers (e.g., the layer 305a) that have been formed in the step 1404. The overlying dielectric material layer may extend into the trench 302. The overlying dielectric material layer 305b may extend beyond the trench 302. The overlying dielectric material layer 305b may cover the first gate structure 301a and the second gate structure 301b. A material of the intermediate dielectric material layer 305a may be the same as a material of the overlying dielectric material layer 305b.

The overlying dielectric material layer 305b may be formed of one or more of flowable silicon dioxide (SiO₂), flowable silicon oxynitride (SiOₓN_{y}), etc. The overlying dielectric material layer 305b may be formed through spin-on deposition (SOD) of one or more dielectric materials, such as SOD of one or more of silicates, siloxanes, methyl silsesquioxane (MSQ), hydrogen silsesquioxane (HSQ), MSQ-HSQ, perhydrosilazane (perhydrosilazane, TCPS), and perhydro-polysilazane (PSZ).

In an embodiment, the overlying dielectric material layer 305b may be formed of flowable silicon dioxide (SiO₂) and may be formed through a flowable chemical vapor deposition (FCVD) process. In the FCVD process, a silicon-containing precursor (e.g., an organic silane) may react with an oxygen-containing precursor (e.g. one or more of oxygen, ozone, and nitrogen oxides) to form the silicon oxide overlying dielectric material layer 305b on the substrate structure 300 and on the elements already positioned on the substrate structure 300. The silicon oxide overlying dielectric material layer 305b may have a substantially high concentration of silicon-hydroxide (Si—OH) bonds. The bonds may promote and/or optimize the flowability (or mobility) of silicon oxide material of the intermediate dielectric material layer, such that the silicon oxide material may rapidly move into gaps and/or trenches on the elements already positioned on the substrate structure 300 and may rapidly cover the gate structures 301a and 301b.

As a result, a dielectric layer 305 that includes the one or more intermediate dielectric material layers (e.g., the layer 305a) and the overlying dielectric material layer 305b may be formed. The dielectric layer 305 may substantially completely fill the trench 302 and may cover both the gate structures 301a and 301b.

Referring to FIG. 14, FIG. 12, and FIG. 13, subsequently to the step 1404, the step 1405 may include performing one or more iterations of a dielectric layer treatment process on the dielectric layer 305. The treatment process may include performing a curing process on the dielectric layer 305 and subsequently performing an annealing process on the dielectric layer 305.

The curing process may involve exposing the dielectric layer 305a to at least one of deionized water and ozone (O₃). In the curing process, the flow rate of ozone may be in a range of 300 sccm to 5000 sccm, the process temperature may be in a range of 30 degrees Celsius to 500 degrees Celsius, and the process pressure may be in a range of 1 torr to 7140 torr. The curing process may transform Si—O bond networks in the dielectric layer 305. As a result, the density of the dielectric layer 305 may be maximized. Advantageously, defects (e.g., voids) in the structure illustrated in FIG. 13 may be substantially minimized or prevented.

The annealing process (represented by dotted arrows in FIG. 13) may include at least one of a steam annealing process, a dry annealing process, a plasma annealing process, an ultraviolet (UV) annealing process, an electron beam annealing process, a microwave annealing process, etc. One or more of dry nitrogen, dry helium, dray argon, etc. may be used in the dry annealing process.

In an embodiment, organic silane may be used as a source gas in the process of forming the dielectric layer 305, such that a substantial amount of carbon may be introduced to the oxide layer to form, for example, Si—C bonds and/or Si—O—C bonds. The annealing process may include a steam annealing process for replacing some Si—C bonds with Si—OH bonds in the dielectric layer 305. In the steam annealing process, the flow rate of water vapor may be in a range of 5 sccm to 20 sccm, and the process temperature may be in a range of 400 degrees Celsius to 500 degrees Celsius, e.g., 450 degrees Celsius. Subsequently, a dry annealing process may be performed on the dielectric layer 305 in a water-free atmosphere, e.g., in a dry nitrogen atmosphere, to convert the Si—OH bonds into silicon oxide bonds and to remove moisture from the dielectric layer 305.

The annealing process may be performed at a temperature in a range of 400 degrees Celsius to 500 degrees Celsius.

In an embodiment, for optimizing the quality of the dielectric layer 305, multiple iterations of the treatment process may be performed in the step 1405. For example, the total number of the iterations of the treatment process may be equal to 3 or 4 in the step 1405. Since the process temperatures for the curing process and the annealing process may be sufficiently low, the iterations of the treatment process may not cause significant damage to elements in the semiconductor device.

An embodiment of the present invention may be related to a high-k metal gate and/or gate-last process that may include one or more of the above-discussed steps. An embodiment of the present invention may be related to an interlayer dielectric layer formation process in a fin field-effect transistor (FinFET) manufacturing process, wherein the interlayer dielectric layer formation process may include one or more of the above-discussed steps.

According to embodiments of the invention, the liner structure and/or the curing, annealing, and process iterations may enable optimization of the density and filling capability of the dielectric layer 305. The sufficiently low process temperatures may prevent the processes from causing damage to elements of the semiconductor device. Therefore, defects (e.g., voids or gaps) in the semiconductor device may be substantially minimized or prevented. Advantageously, satisfactory quality of the semiconductor device and satisfactory manufacturing yield associated with the semiconductor device may be substantially attained.

An embodiment of the present invention may be related to a semiconductor device, which may be manufactured using one or more of the above-discussed steps. Referring to FIG. 5 or FIG. 13, the semiconductor device may include the following elements: a substrate structure (e.g., 100 or 300); a first gate structure (e.g., 101a or 301a) positioned on the substrate structure; a second gate structure (e.g., 101b or 301b) positioned on the substrate structure; a trench (e.g., 102 or 302) positioned between the first gate structure and the second gate structure; a liner (e.g., 104 or 304) that covers the first gate structure, the second gate structure, and a bottom of the trench; and a dielectric layer (e.g., 105 or 305) that covers the liner and fills the trench. The first gate structure may include a dummy gate member formed of silicon.

The first gate structure may include a gate dielectric layer positioned between the dummy gate member and the substrate structure.

The liner may be formed of an oxide material. A minimum thickness of the liner may be in a range of 5 nm to 15 nm.

The semiconductor device may include an etch stop layer positioned between the liner and each of the first gate structure, the second gate structure, and the substrate structure.

An embodiment of the present invention may be related to an electronic device that includes an electronic component and includes a semiconductor device. The semiconductor device may be manufactured using one or more of the above-discussed steps and may be electrically connected to the electronic component.

In an embodiment, the electronic device may be or may include one or more of a mobile phone, a tablet computer, a notebook computer, a netbook, a game console, a television, a video compact disc (VCD) player, a digital video disc (DVD) player, a navigation device, a camera, a camcorder, a voice recorder, an MP3 player, an MP4 player, a portable game device, etc.

In an embodiment, the electronic device may be or may include an intermediate product (e.g., a mobile phone main board) or module including a semiconductor device that may have one or more of the features and advantages discussed above.

According to embodiments of the invention, in a process for manufacturing semiconductor devices, liner formation, liner cleaning, dielectric layer curing, dielectric layer cleaning, dielectric layer annealing, and/or process iterations may enable optimization of density and filling capability of dielectric layers. Sufficiently low process temperatures may prevent processes from causing damage to elements of the semiconductor devices. Therefore, defects (e.g., voids or gaps) in the semiconductor devices may be substantially minimized or prevented. Advantageously, satisfactory quality of the semiconductor devices and a satisfactory yield of the manufacturing process may be substantially attained.

While this invention has been described in terms of several embodiments, there are alterations, permutations, and equivalents, which fall within the scope of this invention. It should also be noted that there are many alternative ways of implementing the methods and apparatuses of the present invention. Furthermore, embodiments of the present invention may find utility in other applications. The abstract section is provided herein for convenience and, due to word count limitation, is accordingly written for reading convenience and should not be employed to limit the scope of the claims. It is therefore intended that the following appended claims be interpreted as including all such alterations, permutations, and equivalents as fall within the true spirit and scope of the present invention.

What is claimed is:

1. A method for manufacturing a semiconductor device, the method comprising:
providing a substrate structure;
providing, on the substrate structure, a first gate structure, a second gate structure, and a trench between the first gate structure and the second gate structure;
providing a liner that covers the first gate structure, the second gate structure, and a bottom of the trench;
after the liner has been provided, providing a dielectric layer that fills the trench; and
performing one or more iterations of a treatment process on the dielectric layer, wherein the treatment process comprises: performing a curing process on the dielectric layer and subsequently performing an annealing process on the dielectric layer.

2. The method of claim 1, wherein the liner is formed of an oxide material.

3. The method of claim 1, wherein the liner is formed through at least one of an atomic layer deposition process and a chemical vapor deposition process, and wherein a minimum thickness of the liner is in a range of 5 nm to 15 nm.

4. The method of claim 1, wherein the providing the dielectric layer comprises:
performing one or more iterations of an intermediate process, wherein the intermediate process comprises: providing an intermediate dielectric material layer in the trench and subsequently performing an intermediate curing process on the intermediate dielectric material layer; and
subsequently providing an overlying dielectric material layer that overlies one or more intermediate dielectric material layers, wherein the dielectric layer comprises the one or more intermediate dielectric material layers and the overlying dielectric material layer.

5. The method of claim 4, wherein the overlying dielectric material layer covers the first gate structure and the second gate structure.

6. The method of claim 5, wherein the overlying dielectric material layer extends into the trench.

7. The method of claim 4, wherein the intermediate process further comprises: after the intermediate curing process, performing a cleaning process on the intermediate dielectric material layer to generate a set of reactive species at the intermediate dielectric material layer.

8. The method of claim 4, wherein two or more iterations of the intermediate process are performed before the overlying dielectric material layer is provided.

9. The method of claim 1, further comprising: before the providing the dielectric layer, performing a cleaning process on the liner to generate a set of reactive species at the liner.

10. The method of claim 7, wherein at least one of ammonia, hydrogen peroxide, deionized water, and ozone is used in the cleaning process.

11. The method of claim 1, wherein at least one of deionized water and ozone is used in the curing process.

12. The method of claim 1, wherein the annealing process includes at least one of a steam annealing process and a dry annealing process.

13. The method of claim 1, wherein the annealing process is performed at a temperature in a range of 400 degrees Celsius to 500 degrees Celsius.

14. The method of claim 1, wherein a total number of the iterations of the treatment process is equal to 3 or 4.

15. The method of claim 1, further comprising: before the liner is provided, providing an etch stop layer on the first gate structure, the second gate structure, and the bottom of the trench, wherein the liner is formed on the etch stop layer.

16. The method of claim 1, wherein the first gate structure comprises: a dummy gate member formed of silicon; and a gate dielectric layer positioned between the dummy gate member and the substrate structure.

17. A semiconductor device comprising:
a substrate structure;
a first gate structure positioned on the substrate structure;
a second gate structure positioned on the substrate structure;
a trench positioned between the first gate structure and the second gate structure;
a liner that covers the first gate structure, the second gate structure, and a bottom of the trench; and
a dielectric layer that covers the liner and fills the trench.

18. The semiconductor device of claim 17, wherein the liner is formed of an oxide material.

19. The semiconductor device of claim 18, wherein a minimum thickness of the liner is in a range of 5 nm to 15 nm.

20. The semiconductor device of claim 18, further comprising: an etch stop layer positioned between the liner and each of the first gate structure, the second gate structure, and the substrate structure, wherein the first gate structure comprises: a dummy gate member formed of silicon; and a gate dielectric layer positioned between the dummy gate member and the substrate structure.
